(19) United States
(12) Patent Application Publication
(10) Pub. No.: US 2025/0151633 A1
(43) Pub. Date: May 8, 2025

(54) SPIN QUBIT ELECTRONIC DEVICE

(71) Applicant: Commissariat à I'Énergie Atomique et aux Énergies Alternatives, Paris (FR)

(72) Inventor: Benoit Bertrand, Grenoble (FR)

(73) Assignee: Commissariat à I'Énergie Atomique et aux Énergies Alternatives, Paris (FR)

(21) Appl. No.: 18/938,562

(22) Filed: Nov. 6, 2024

(30) Foreign Application Priority Data
Nov. 7, 2023 (FR) 2312057

(51) Int. Cl. H10N 69/00; H10N 60/01; H10N 60/10

(52) U.S. Cl. CPC H10N 69/00; H10N 60/01; H10N 60/11; H10N 60/128

(57) ABSTRACT

An electronic device including: a support; a semiconductor fin arranged on the support, in which quantum dots are intended to be formed; a plurality of separate first control gates, arranged on the side of a first lateral surface of the fin, one above the other and defining different gate levels, configured to each control the electrostatic potential of one of the quantum dots; at least one second control gate arranged on the side of a second lateral surface of the fin, and configured to control the electrostatic potential of a coupling region between the quantum dots; wherein the second control gate is offset, along a direction perpendicular to the upper surface of the support, with respect to the first control gates.

### CROSS REFERENCE TO RELATED APPLICATIONS

This application claims priority to French application number 2312057, filed Nov. 7, 2023, the contents of which is incorporated by reference in its entirety.

### TECHNICAL FIELD

The present disclosure generally concerns the field of spintronics, of quantum devices, and of quantum computing.

### PRIOR ART

There exist quantum devices comprising qubits based on the forming of quantum dots ensuring the confinement of elementary charges (electrons or holes). In these devices, the quantum information is, for example, encoded on the spin of these particles. Quantum dots are formed by means of gates, via which electric confinement potentials are created in a semiconductor material. These gates enable to locally adjust the electrostatic potential of the quantum dots, that is, the depth of the potential wells of the quantum dots. These devices can also include other gates electrically controlling the tunnel coupling, that is, the height of the tunnel barriers, between neighboring quantum dots.

In practice, electrically-charged defects are present in materials, for example at the Si-SiO₂ interfaces of quantum dots, and locally disturb the electrostatic potential of quantum dots and of tunnel barriers. The electrostatic disorder generated by these defects superimposes to the electrostatic potentials generated by the gates.

A way of decreasing the impact of this electrostatic disorder is to decrease the pitch with which the gates are formed, that is, to decrease the length and the spacing between two neighboring gates, so that this pitch is smaller than the characteristic length of the disorder to be able to compensate for it or to work at a scale smaller than this disorder. However, the pitch achievable with available lithography tools remains insufficient to properly compensate for the impact of electrically-charged defects.

Document WO 2019/125348 A1 describes a quantum device in which the qubit array is vertically integrated. Such a configuration enables to decrease the achievable pitch as compared with devices in which the gates are all arranged in a same plane.

### SUMMARY OF THE INVENTION

There is provided an electronic device which does not have one or more of the previously-described disadvantages, and enabling to obtain pitch values not achievable by the known above-described structures.

An embodiment provides a solution to all or part of the disadvantages of known solutions and provides an electronic device comprising:
a support;
a semiconductor fin arranged on an upper surface of the support, in which quantum dots are intended to be formed, and comprising a first lateral surface and a second lateral surface opposite to the first lateral surface;
a plurality of first control gates separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1, and Z corresponding to an integer greater than or equal to 2;
at least one second control gate arranged on the side of the second lateral surface, and configured to control the electrostatic potential of a coupling region intended to be formed between the quantum dots;
wherein said at least one second control gate is offset, along the direction perpendicular to the upper surface of the support, with respect to the first control gates and defines a gate level interposed between two other gate levels, each comprising one of the first control gates.

There is also provided an electronic device comprising:
a support;
a semiconductor fin arranged on an upper surface of the support, in which quantum dots are intended to be formed, and comprising a first lateral surface and a second lateral surface opposite to the first lateral surface;
a plurality of first control gates separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1,and Z corresponding to an integer greater than or equal to 2;
at least one second control gate arranged on the side of the second lateral surface, and configured to control the electrostatic potential of a coupling region intended to be formed between the quantum dots;
wherein the control gate(s) arranged on the side of the second surface are offset, along the direction perpendicular to the upper surface of the support, with respect to the control gates arranged on side of the first lateral surface and define one or a plurality of gate levels, each interposed between two other gate levels each comprising one of the control gates arranged on the side of the first lateral surface.

According to a specific embodiment, the first control gates are arranged on the side of the first lateral surface only, and said at least one second control gate is arranged on the side of the second lateral surface only.

According to a specific embodiment, a first portion of the upper surface of the support on which are arranged the first control gates is offset, along the direction perpendicular to the upper surface of the support, with respect to a second portion of the upper surface of the support on which is arranged the second control gate.

According to a specific embodiment, the device further comprises at least one first dielectric portion arranged between the first control gates.

According to a specific embodiment, the device comprises a plurality of second control gates arranged on the side of the second lateral surface one above the other along the direction perpendicular to the upper surface of the support and defining different gate levels, configured to each control the electrostatic potential of a coupling region intended to be formed between two of the quantum dots,

[symbol]

[symbol] and the second control gates are offset, along the direction perpendicular to the upper surface of the support, with respect to the first control gates, each of the second control gates being arranged in a gate level interposed between two other gate levels each comprising one of the first control gates.

According to a specific embodiment, the device further comprises a plurality of first dielectric portions arranged between the first control gates and a plurality of second dielectric portions arranged between the second control gates.

According to a specific embodiment, in a direction perpendicular to the lateral surfaces, each of the first control gates has a width different from that of the other first control gates, and each of the second control gates has a width different from that of the other second control gates.

According to a specific embodiment, a dimension of the semiconductor fin perpendicular to the first and second lateral surfaces is such that a single plane or two planes of quantum dots parallel to the first and second lateral surfaces are intended to be formed in the semiconductor fin.

According to a specific embodiment, heights, along the direction perpendicular to the upper surface of the support, of the first and second control gates, are equal to one another.

According to a specific embodiment, in a plane perpendicular to the upper surface of the support and perpendicular to the first and second lateral surfaces, the first and second control gates are aligned with respect to one another, or the first control gates are offset with respect to the second control gates.

According to a specific embodiment, the device comprises a plurality of distinct sets of first and second control gates arranged along a length of the semiconductor fin which corresponds to a dimension parallel to the first and second lateral surfaces and to the upper surface of the support.

There is also provided a method of forming an electronic device, comprising:
forming a semiconductor fin on an upper surface of the support, in which quantum dots are intended to be formed, and comprising a first lateral surface and a second lateral surface opposite to the first lateral surface;
forming a plurality of first control gates separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1,and Z corresponding to an integer greater than or equal to 2;
forming at least one second control gate arranged on the side of the second lateral surface, and configured to control the electrostatic potential of a coupling region intended to be formed between the quantum dots;
wherein said at least one second control gate is offset, along the direction perpendicular to the upper surface of the support, with respect to the first control gates and defines a gate level interposed between two other gate levels, each comprising one of the first control gates.

There is also provided a method of forming an electronic device, comprising:
forming a semiconductor fin on an upper surface of the support, in which quantum dots are intended to be formed, and comprising a first lateral surface and a second lateral surface opposite to the first lateral surface;
forming a plurality of first control gates separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1,and Z corresponding to an integer greater than or equal to 2;
forming at least one second control gate arranged on the side of the second lateral surface, and configured to control the electrostatic potential of a coupling region intended to be formed between the quantum dots;
wherein the control gate(s) arranged on the side of the second lateral surface are offset, along the direction perpendicular to the upper surface of the support, with respect to the control gates arranged on the side of the first lateral surface and define one or a plurality of gate levels, each interposed between two other gate levels, each comprising one of the control gates arranged on the side of the first lateral surface.

According to a specific embodiment, forming the semiconductor fin comprises at least one etching of the support, and the first and second control gates are then formed on remaining portions of the support arranged on either side of the semiconductor fin.

According to a specific embodiment, forming the semiconductor fin comprises at least one epitaxial growth from a region of the support forming a bottom wall of an opening formed through a stack of layers arranged on the support and from which the first and second control gates are formed.

According to a specific embodiment, forming the first and second control gates comprises at least the implementation of the following steps:
forming a stack of layers of a first semiconductor and of layers of a second semiconductor arranged in alternating fashion one above the other, the first and second semiconductors being capable of being selectively etched over one another;
etching of the stack in such a way that at least two remaining portions of the stack are each arranged against one of the first and second side walls;
selective removal of remaining portions of the second semiconductor layers present in the remaining portions of the stack;
deposition of at least one dielectric material in spaces formed by the selective removal of the remaining portions of the layers of the second semiconductor, forming first dielectric portions arranged between the first control gates and second dielectric portions arranged between a plurality of second control gates;
and the semiconductor fin is formed before the stack.

According to a specific embodiment, forming the first and second control gates comprises at least the implementation of the following steps:
forming a stack of layers of an electrically-conductive material and of layers of a dielectric material arranged in alternating fashion one above the other;
etching of the stack in such a way that at least two remaining portions of the stack are each arranged against one of the first and second lateral walls;
and the stack of layers is formed after the semiconductor fin and by implementing successive steps of deposition of the layers of electrically-conductive material and of the layers of dielectric material and, between the deposition steps, steps of removal of portions of the layers of electrically-conductive material and of the layers of dielectric material deposited against the first and second lateral surfaces.

According to a specific embodiment, forming the first and second control gates comprises at least the implementation of the following steps:
forming a stack of layers of an electrically-conductive material and of layers of a dielectric material arranged in alternating fashion one above the other;
etching of the stack in such a way that at least two remaining portions of the stack of layers are each arranged against one of the first and second lateral walls; and the semiconductor fin is formed after the stack.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an example of an electronic device according to a specific embodiment;

FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, FIG. 17, FIG. 18, FIG. 19, FIG. 20, FIG. 21, FIG. 22, FIG. 23, and FIG. 24 show steps of a method of manufacturing an electronic device according to a specific embodiment;

FIG. 25, FIG. 26, FIG. 27, and FIG. 28 show steps of a variant of a method of forming an electronic device according to a specific embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings. However, there terms give no information regarding the actual position and orientation of the device during its use.

Unless specified otherwise, the expressions “about”, “approximately”, “substantially”, and “in the order of” signify plus or minus 10%, preferably of plus or minus 5%.

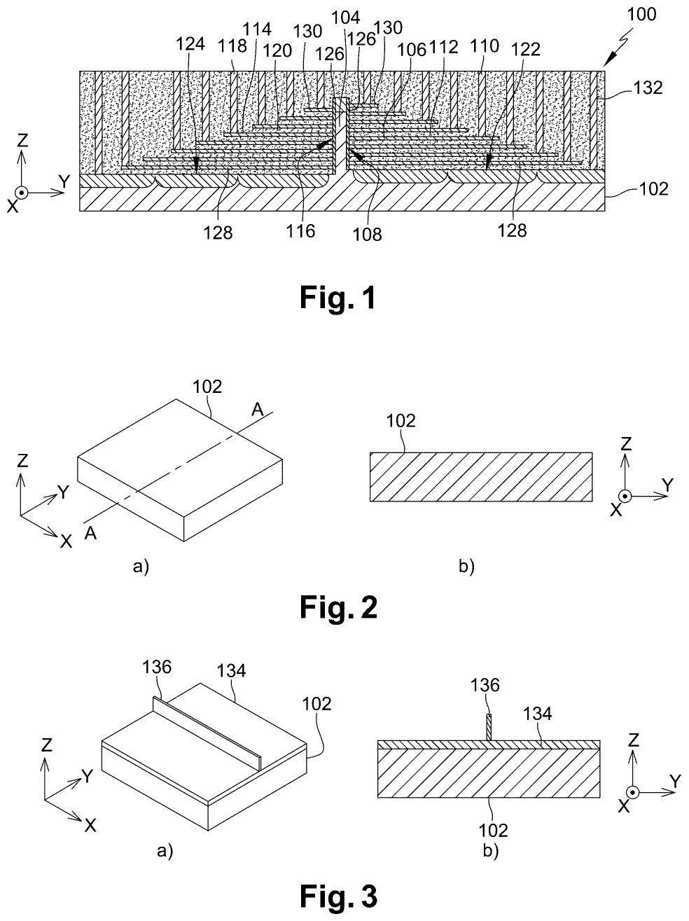

An example of an electronic device 100 according to a specific embodiment is described hereafter in relation with FIG. 1, which is a cross-section view of device 100.

In the described example, device 100 comprises at least one support 102 on which is arranged at least one semiconductor fin 104. According to a specific embodiment of device 100, fin 104 may correspond to a portion of a semiconductor surface layer of a substrate of semiconductor-on-insulator type, for example SOI (Silicon On Insulator). Support 102, in this case, may correspond to the stack comprising the buried dielectric layer arranged on the solid semiconductor layer of the substrate of semiconductor-on-insulator type. The buried dielectric layer corresponds, for example, to an SiO₂ layer and the solid layer comprises, for example, silicon.

For example, fin 104 may comprise silicon when the qubits intended to be used in device 100 correspond to electron qubits. As a variant, fin 104 may for example comprise germanium when the qubits intended to be used in device 100 correspond to hole qubits.

As a variant, fin 104 may not correspond to a portion of a surface layer of a substrate of semiconductor-on-insulator type, and be formed, for example by deposition or any other suitable technique, on top of or from another type of support 102 corresponding, for example, to a bulk or solid substrate capable of comprising semiconductor material such as a semiconductor wafer.

In the described embodiment, a width W of fin 104, corresponding to the dimension parallel to the Y axis shown in FIG. 1, is for example in the range from 10 nm to 50 nm. A thickness H of fin 104, corresponding to the dimension parallel to the Z axis shown in FIG. 1, is for example in the range from 100 nm to 1 μm. The value selected for this thickness is in particular a function of the number of gate levels of device 100 intended to be stacked one above the other, and thus on the number of quantum dots and of possible charge detectors and carrier reservoirs intended to be formed in fin 104. Finally, a length L of fin 104, corresponding to the dimension parallel to the X axis shown in FIG. 1, is for example in the range from 500 nm to 10 μm.

In this example of embodiment, device 100 comprises at least two first control gates 106 separate from each other, arranged one above the other, and each covering a portion of a first lateral surface 108 of fin 104 (surface parallel to the (X,Z) plane in FIG. 1). The first gates 106 are configured to each control the electrostatic potential of one of the quantum dots intended to be formed in fin 104 and to be submitted to the electrostatic control of the first gates 106, this electrostatic control being obtained via the electric potential intended to be applied to each of these first gates 106. Each of the first gates 106 comprises at least one electrically-conductive portion. The first gates 106 define different gate levels called first gate levels. The first gate 106 closest to support 102 is arranged in a gate level N, and the first gate 106 most distant from support 102 is arranged in a gate level N+Z, with N corresponding to an integer greater than or equal to 1, and Z corresponding to an integer greater than or equal to 2.

In the example of FIG. 1, device 100 comprises more than two first gates 106. Device 100 however comprises a number of first gates 106 which is a function of the number of quantum dots intended to be formed in fin 104.

In a specific configuration of device 100, each of the first gates 106 may comprise at least one electrically-conductive material such as doped single-crystal silicon and/or silicide, or polysilicon, or a stack of a plurality of materials.

In a specific configuration of device 100, each of the first gates 106 has a length L_{G1} (dimension parallel to the length L of fin 104) for example in the range from 15 nm to 50 nm, and a height H_{G1} (dimension parallel to the height H of fin 104) for example in the range from 5 nm to 15 nm. The height H_{G1} of the first gates 106 is in particular a function of the material(s) used to form these first gates 106 and on the technique(s) implemented to form these first gates 106.

In the example of embodiment of the device 100 described and shown in FIG. 1, each of the first gates 106 has, along an axis perpendicular to the first lateral surface 108, a width W_{G1} different from those of the other first gates 106. As can be seen in FIG. 1, the values of the widths W_{G1} of the first gates 106 are decreasing in the direction from the base of fin 104 arranged against support 102 to the top of fin 104 (direction parallel to the Z axis shown in FIG. 1). Thus, the end of each of the first gates 106 is not arranged opposite one or plurality of the other first gates 106 located above this first gate 106. These ends can thus be used as electrical access to each of the first gates 106. In the example of FIG. 1, these electrical accesses to the first gates 106 are provided by first electrical contacts 110, each electrically coupled to the end of one of the first gates 106. The first electrical contacts 110 for example comprise at least one metallic material such as Ti, TiN, or W.

In a specific configuration of device 100, each of the first gates 106 is electrically insulated from the neighboring first gate(s) 106 (located above and/or below the first gate 106 in question) by first dielectric portions 112 interposed between them. Thus, two neighboring first gates 106 arranged one above the other are separate from each other by a distance equal to the thickness (dimension parallel to the height H of fin 104) of one of the first dielectric portions 112, which is, for example, in the range from 5 nm to 15 nm. The first dielectric portions 112 for example comprise SiO₂ or any other dielectric material adapted to electrically insulating the neighboring first gates 106 from each other.

In the described embodiment, device 100 comprises at least one second control gate 114 covering a portion of a second lateral surface 116, opposite to the first lateral surface 108, of fin 104. In FIG. 1, this second lateral surface 116 is parallel to the (X,Z) plane. The second gate 114 is configured to control the electrostatic potential of a coupling region intended to be formed in fin 104 between two quantum dots and to be submitted to the electrostatic control of the second gate 114, this electrostatic control being obtained via the electric potential intended to be applied to the second gate 114. The second gate 114 comprises at least one electrically-conductive portion. The second gate 114 defines a gate level called the second gate level, which is interposed between two other first gate levels, each comprising one of the first gates 106.

In the example of FIG. 1, device 100 comprises a plurality of second gates 114. Device 100 however comprises a number of second gates 114 which is a function of the number of coupling regions intended to be controlled in fin 104. Each of the second gates 114 is arranged in a second gate level interposed between two other first gate levels, each comprising one of the first gates 106.

In a specific configuration of device 100, each of the second gates 114 may comprise at least one electrically-conductive material such as doped single-crystal silicon and/or silicide, or polysilicon, or a stack of a plurality of materials. In an advantageous configuration, the material(s) of the second gates 114 are similar to that or those of the first gates 106.

In a specific configuration of device 100, each of the second gates 114 has a length L_{G2} (dimension parallel to the length L of fin 104) for example in the range from 15 nm to 50 nm and which is for example equal to length L_{G1}. Further, each of the second gates 114 may have a height H_{G2} (dimension parallel to the height H of fin 104) for example in the range from 5 nm to 15 nm and which is for example equal to height H_{G1}. The height H_{G2} of the second gates 114 depends in particular on the material(s) used to form these second gates 114 as well as on the technique(s) implemented to form these second gates 114.

In the described example of embodiment, as with the first gates 106, each of the second gates 114 has, along an axis perpendicular to the second lateral surface 116, a width W_{G2} different from those of the other second gates 114. As can be seen in FIG. 1, the values of the widths W_{G2} of the second gates 114 are decreasing in the direction from the base of fin 104 arranged against support 102 to the top of fin 104 (direction parallel to the Z axis shown in FIG. 1). Thus, the end of each of the second gates 114 is not arranged opposite one or a plurality of the other second gates 114 located above this second gate 114. These ends can thus be used as electrical accesses to each of the second gates 114. In the example of FIG. 1, these electrical accesses to the second gates 114 are provided by second electrical contacts 118, each electrically coupled to the end of one of the second gates 114. The second electrical contacts 118 comprise, for example, at least one metallic material such as Ti, TiN, or W, and comprise, for example, the same material(s) as those forming the first electrical contacts 110.

In a specific configuration of device 100, each of the second gates 114 is electrically insulated from the neighboring second gate(s) 114 (located above and/or below the second gate 114 in question) by second dielectric portions 120 interposed between them. Thus, two neighboring second gates 114 arranged one above the other are spaced apart by a distance equal to the thickness (dimension parallel to the height H of fin 104) of one of the second dielectric portions 120, which is, for example, in the range from 5 nm to 15 nm and is, for example, equal to the thickness of one of the first dielectric portions 112. The second dielectric portions 120 for example comprise SiO₂ or any other dielectric material adapted to electrically insulating the neighboring second gates 114 from each other. The second dielectric portions 120 advantageously comprise the same dielectric material(s) as those forming the first dielectric portions 112.

In device 100, the first gates 106 are not aligned, in a plane parallel to their width W_{G1} and to their length L_{G1} (plane parallel to the (X,Y) plane in FIG. 1), with the second gates 114, that is, are not arranged entirely, or totally, opposite the first gates 106. In other words, at least part of the orthogonal projections of the portions of the second lateral surface 116 covered by the second gates 114 onto the first lateral surface 108 is arranged between the portions of the first lateral surface 108 covered by the first gates 106. Advantageously, the first and second gates 106, 114 are arranged alternately in different gate levels along the dimension parallel to the thickness H of fin 104, that is, along the Z axis. In other words, the first gate levels and the second gate levels are alternately arranged along the dimension parallel to the thickness H of fin 104.

In the described example of embodiment, this offset between the first gates 106 and the second gates 114 results from the fact that a first portion 122 of an upper surface of support 102 (on which are arranged the first gates 106) is arranged in a plane different from that in which is arranged a second portion 124 of the upper surface of support 102 (on which are arranged the second gates 114). The difference in height (dimension parallel to the Z axis) between the first and second portions 122, 124 of the upper surface of support 102 is for example equal to the thickness of one of the first and second dielectric portions 112, 120 and which corresponds, for example, to the thickness H_{G1}, H_{G2} of one of the first or second gates 106, 114. In the example of embodiment shown in FIG. 1, the thickness of the portion of support 102 including the first portion 122 of its upper surface is greater than that including the second portion 124 of its upper surface. As a variant, it is possible for the thickness of the portion of support 102 including the first portion 122 of its upper surface to be smaller than that including the second portion 124 of its upper surface.

As a variant, it is possible for the offset between the first gates 106 and the second gates 114, parallel to their height, not to be due to a height difference between the first and second portions 122, 124 of the upper surface of support 102, but to an additional portion of material present only on one of these first and second portions 122, 124 of the upper surface of support 102 and on which the first gates 106 or the second gates 114 are formed.

In the example of embodiment shown in FIG. 1, the orthogonal projections of the portions of the second lateral surface 116 covered by the second gates 114 onto the first lateral surface 108 are arranged between the portions of the first lateral surface 108 covered by the first gates 106, with no overlapping between these projected portions of the second lateral surface 116 and those of the first lateral surface 108 covered by the first gates 106. As a variant, it is possible to have a partial overlapping of the projected portions of the second lateral surface 116 and those of the first lateral surface 108 covered by the first gates 106. For example, this partial overlapping may be such that, at most, half the surface area of each of the orthogonal projections of the portions of the second lateral surface 116 covered by the second gates 114 onto the first lateral surface 108 covers one of the portions of the first lateral surface 108 covered by the first gates 106.

In the example of embodiment of the described device 100, the lateral surfaces 108, 116 of fin 104 are covered with a dielectric layer 126 intended in particular to be used as a gate oxide for the first gates 106 and the second gates 114. Dielectric layer 126 comprises, for example, SiO₂ and/or Al₂O₃ and/or HfO₂. The thickness of dielectric layer 126 is, for example, in the range from 2 nm to 20 nm.

In the rest of the disclosure, reference is made to a plurality of second control gates 114 of device 100. However, the various features described in relation with the second control gates 114 would also apply to the single second control gate 114 of device 100 if device 100 only had a single second control gate 114.

During the operation of device 100, an electric potential, for example in the range from 50 mV to 150 mV, may be applied to the first gates 106 to create the quantum dots in fin 104. The second gates 116 are used to couple or decouple the qubits from the quantum dots 114 according to needs, by applying thereto electric potentials, for example in the range from −3 V to +3 V, generating an attractive or repulsive effect, of positive or negative value.

Device 100 may further comprise a plurality of third gates 128 separate from one another, arranged under the first and second gates 106, 114 and each covering a portion of one of the first and second lateral surfaces 108, 116. In a specific configuration, it is possible to have a plurality of separate third gates 128, stacked one above the other and arranged under the first gates 106, as well as other separate third gates 128, stacked one above the other and arranged under the second gates 114. The third gates 128 have, for example, a length (dimension parallel to the length L of fin 104) and a height (dimension parallel to the height H of fin 104) similar to those of the first gates 106 and/or of the second gates 114. The material(s) of these third gates 128 are, for example, similar to those of the first gates 106 and/or of the second gates 114. The third gates 128 are here arranged in gate levels lower than, or below, those comprising the first and second gates 106, 114.

Device 100 may further comprise a plurality of fourth gates 130, separated from one another, arranged above the first and second gates 106, 114 and each covering a portion of one of the first and second lateral surfaces 108, 116. In a specific configuration, it is possible to have a plurality of separate fourth gates 130, stacked one above the other and arranged above the first gates 106, as well as other separate fourth gates 130, stacked one above the other and arranged above the second gates 114. The fourth gates 130 for example have a length (dimension parallel to the length L of fin 104) and a height (dimension parallel to the height H of fin 104), for example similar to those of the first gates 106 and/or of the second gates 114. The material(s) of these fourth gates 130 are, for example, similar to those of the first gates 106 and/or of the second gates 114. The fourth gates 130 are here arranged in gate levels higher than, or above, those comprising the first and second gates 106, 114.

The third and fourth gates 128, 130 arranged on the same side as the first gates 106, that is, those each covering a portion of the first lateral surface 108, may be used to control the electrostatic potentials of charge detectors formed in portions of fin 104 between which the quantum dots are intended to be formed and/or used as current leads from carrier reservoirs to the charge detectors and/or quantum dots.

The third and fourth gates 128, 130 arranged on the same side as the second gates 114, that is, those each covering a portion of the second lateral surface 116, may be used to control the coupling regions between the charge detectors and the quantum dots and/or the coupling regions between the current leads and the charge detectors or between the current leads and the quantum dots.

The height offset previously described between the first gates 106 and the second gates 114 can also be found between the third gates 128 located on either side of fin 104 and also between the fourth gates 130 located on either side of fin 104. Further, when device 100 comprises the third gates 128 and the fourth gates 130, first dielectric portions 112 and second dielectric portions 120 are also arranged between neighboring third gates 128, between the third gates 128 and the other neighboring gates, between neighboring fourth gates 130, and between the fourth gates 130 and the other neighboring gates. The electrical contacts of the third and fourth gates 128, 130 may also be ensured by electrical contacts similar to the first and second electrical contacts 110, 118.

In the described example of embodiment, device 100 also comprises a dielectric encapsulation material 132 covering the stack of gates 106, 114, 128, 130, fin 104, and the portions of support 102 not covered by the gates. In the presence of such a dielectric encapsulation material 132, the electrical contacts 110, 118 may be formed through this dielectric encapsulation material 132. This dielectric encapsulation material 132 corresponds, for example, to SiO₂.

This specific pattern of gates 106, 114 may be repeated, for example periodically, thus forming a plurality of distinct sets of first and second control gates 106, 114 arranged along the length of fin 104 (dimension parallel to the X axis), thus multiplying the number of qubits that can be formed in fin 104.

In the previously described examples, the first gates 106 and the second gates 114 are aligned with one another, considering a plane parallel to the (Y, Z) plane, that is, a plane which is both perpendicular to the upper surface of support 102 and to the first and second lateral surfaces 108, 116 of fin 104. As a variant, it is possible to have an offset, along the X axis, of the first gates 106 with respect to the second gates 114.

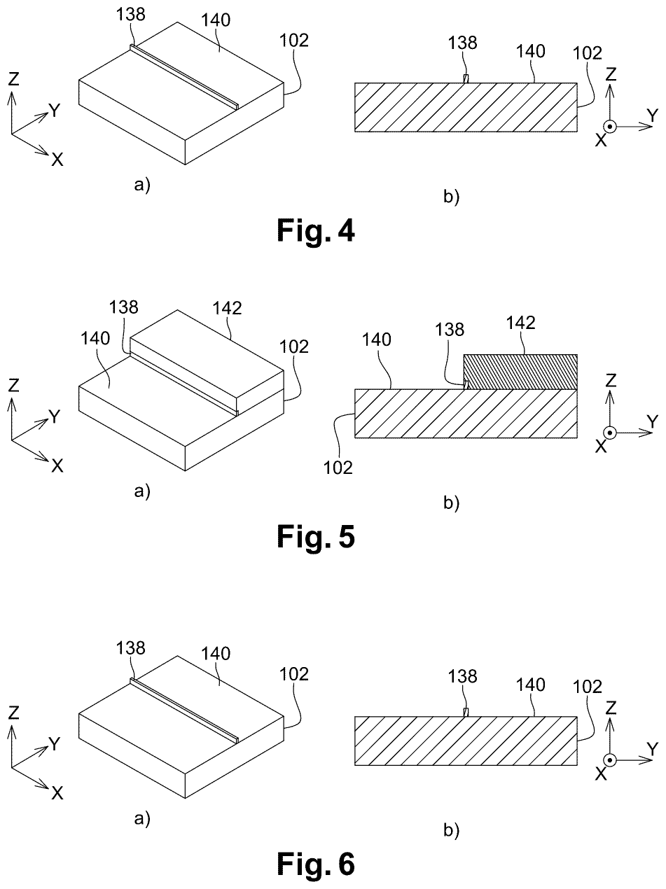

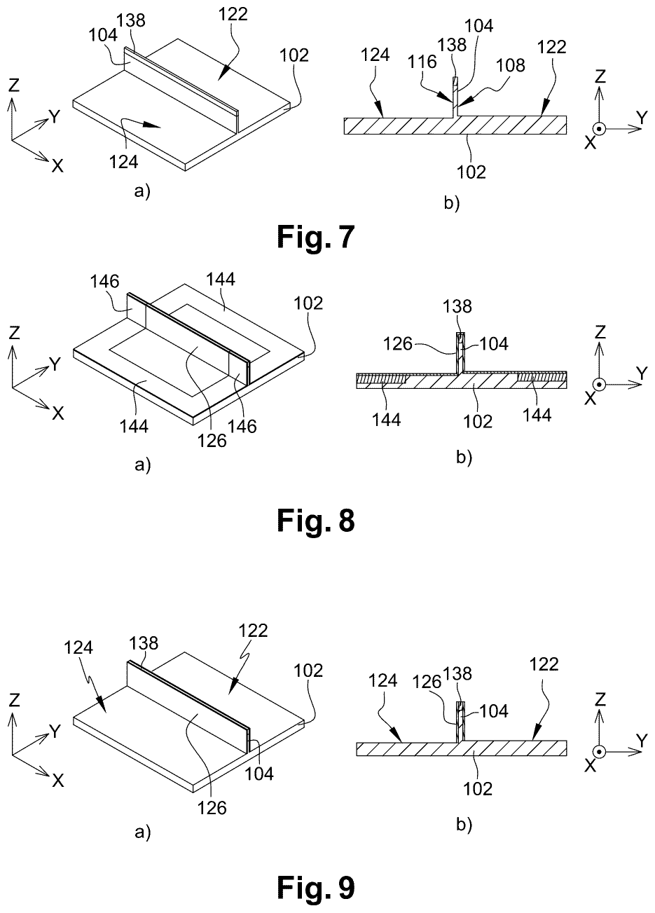

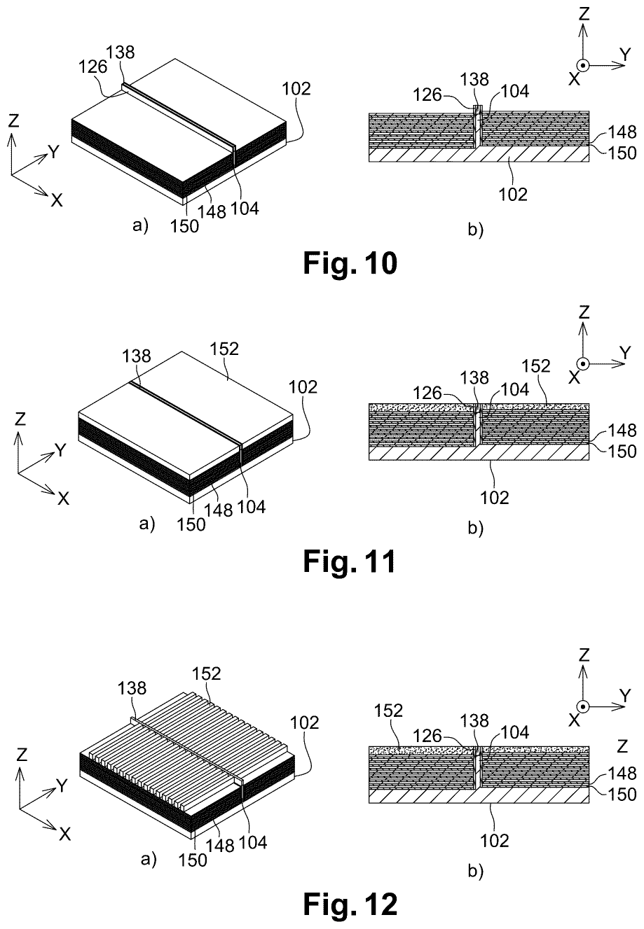

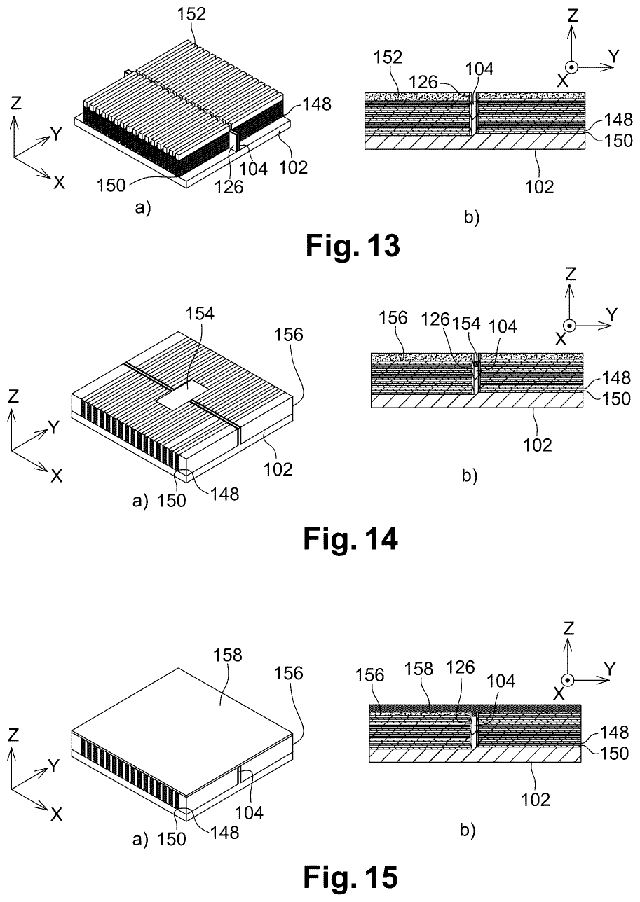

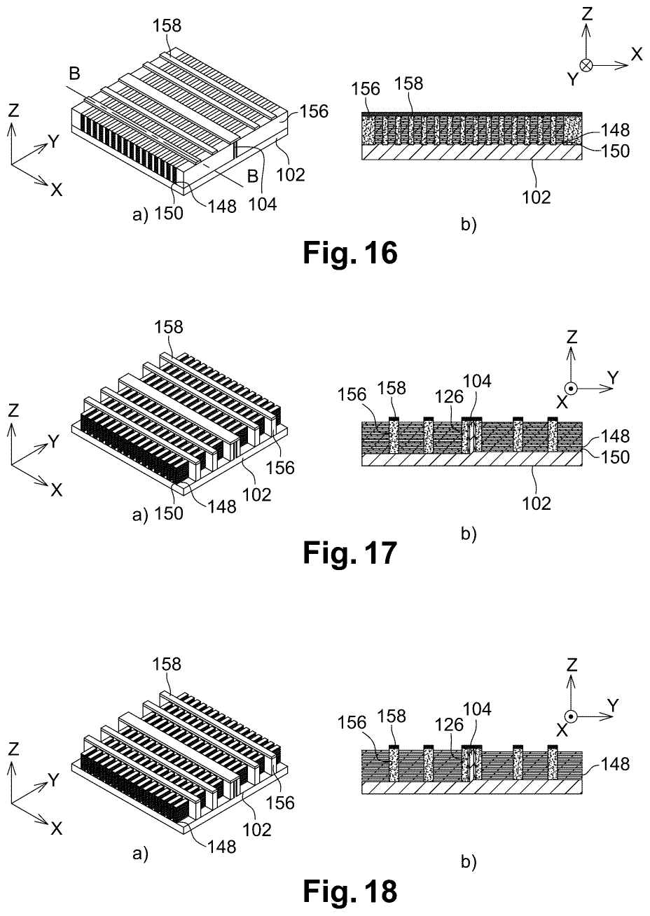

An example of a method of manufacturing electronic device 100 is described below in relation with FIGS. 2 to 24. In each of FIGS. 2 to 22, view a) corresponds to a perspective view of the formed structure, and view b) corresponds to a cross-section view of the formed structure, this cross-section view being taken along an axis (AA) for FIGS. 2 to 15, 17 to 20, and 22, and along an axis (BB) for FIGS. 16 and 21. FIGS. 23 and 24 correspond to cross-section views taken along axis AA.

In this example, fin 104 is first formed. In the described example, fin 104 is formed from support 102, which corresponds to a solid semiconductor substrate, for example silicon or germanium (see FIG. 2).

To form fin 104, a hard mask layer 134, comprising for example SiN, is deposited on support 102 (see FIG. 3). This layer 134 is then etched according to the pattern desired for fin 104. In the example of FIG. 3, a lithography resin 136 is formed on layer 134 according to the pattern desired for fin 104.

The hard mask obtained at the end of this etching is designated with reference 138 and can be seen in FIG. 4. Optionally, an oxidation of the semiconductor surface of support 102 may be implemented. In the example of FIG. 4, this oxidation forms a layer 140 of semiconductor oxide, for example SiO₂, when substrate 102 comprises silicon.

Support 102 is then etched in such a way that the first portion 122 of the upper surface of support 102 is arranged in a plane different from that in which the second portion 124 of the upper surface of support 102 is arranged. To achieve this, a lithography is implemented by using a resin 142 masking hard mask 138 and the portion of support 102 (and thus also of layer 140 if an oxidation of the support 102 has been previously implemented) intended to be thicker than the other, that is, the portion intended to include the first portion 122 of the upper surface of support 102 (see FIG. 5).

The portion of support 102 (and possibly of layer 140 if it is present) not covered by resin 142 is then partially etched so as to obtain the height difference subsequently desired between the first and second portions 122, 124 of the upper surface of support 102. Resin 142 is then removed (see FIG. 6).

Fin 104 is then completed by implementing an etching of support 102 (and possibly of the remaining portion of layer 140 previously covered by resin 142, if it is present). The portion of support 102 covered by hard mask 138 is protected from this etching and forms fin 104. This etching is stopped when the desired height H of fin 104 is obtained. This etching also forms the first and second portions 122, 124 of the upper surface of support 102 on which the first and second gates 106, 114 will be formed. The structure obtained at this stage of the method is shown in FIG. 7.

As a variant, fin 104 may be formed by etching of the surface layer of an SOI substrate. Other variants may also be implemented to form fin 104 on support 102.

In the described example, carrier reservoirs are then formed, for example by masking the regions of support 102 and of fin 104 in which the carrier reservoirs are not formed and by implementing an implantation of dopants in the unmasked regions. In FIG. 8, the regions of the upper surface of support 102 through which the dopants are implanted are designated with reference 144, and the formed carrier reservoirs correspond to the regions of fin 104 in which the dopants are implanted, these reservoirs being designated with reference 146. In the described example, these carrier reservoirs 146 are located at the ends of fin 104. For simplification, the doped regions 144 of support 102 and the carrier reservoirs 146 formed in fin 104 are no longer shown in FIGS. 9 and the following.

Dielectric layer 126 is then formed. The dielectric material may be formed over the entire obtained structure, in the form of a conformal deposit (substantially constant thickness over all the walls against which the dielectric material is deposited) as can be seen in FIG. 8. As a variant, it is possible to form this dielectric layer 126 by implementing a thermal oxidation of the semiconductor of fin 104 and of the other accessible portions of support 102, in particular the portions 122, 124 of the upper surface of support 102. When such a thermal oxidation is implemented, the dielectric layer is not formed against the walls of hard mask 138. The implementation of such a thermal oxidation with a support 102 and a fin 104 comprising silicon forms a dielectric layer 126 comprising SiO₂.

The portions of dielectric layer 126 which do not cover the side walls 108, 116 of fin 104 are then removed, in particular the portions of dielectric layer 126 located on the portions 122, 124 of the upper surface of support 102 and possibly the portion of dielectric layer 126 located on the top of fin 104 (see FIG. 9). The removal of these portions of dielectric layer 126 is for example obtained by implementing an anisotropic etching of dielectric layer 126.

The first and second gates 106, 114 are then formed in such a way that each covers a portion of one of the lateral surfaces 108, 116 of fin 104. To form these gates, the following steps are for example implemented.

A stack of layers of a first semiconductor 148 and of layers of a second semiconductor 150 alternately arranged one above the other is formed on the portions 122, 124 of the upper surface of support 102, that is, on either side of fin 104 and against the dielectric layer 126 formed against the lateral surfaces 108, 116 of fin 104 (see FIG. 10). The first and second semiconductors are selected in such a way that they are capable of being selectively etched with respect to each other. As an example, the thickness of each of layers 148, 150 may be in the range from 5 nm to 15 nm. Such a stack of layers 148, 150 may be formed by implementing successive epitaxy steps. According to an advantageous example of embodiment, layers 148 may comprise silicon and layers 150 may comprise SiGe.

The resulting stack is then etched according to the geometry desired for the first and second gates 106, 114.

For this purpose, a hard mask layer 152 is deposited on the resulting structure, that is, on the stack of layers 148, 150 and on hard mask 138. A chemical-mechanical planarization, or CMP, is then implemented with a stop on hard mask 138 (see FIG. 11).

A lithography is then implemented to transfer the desired pattern of the first and second gates 106, 114 into hard mask layer 152, and hard mask layer 152 is then etched according to this pattern, the remaining portions of hard mask layer 152 covering the portions of the stack of layers 148, 150 intended for the forming of the first and second gates 106, 114. As can be seen in FIG. 12, the remaining portions of hard mask layer 152 arranged on the side of the first lateral surface 108 of fin 104 and defining the pattern of the first gates 106 are arranged opposite those arranged on the side of the second lateral surface 116 of fin 104 and which define the pattern of the second gates 114.

The stack of layers is then etched according to the pattern defined by the remaining portions of hard mask layer 152, this etching being stopped when support 102 is reached. Hard mask 138 is also removed, for example by etching (see FIG. 13).

Optionally, an implantation step may be implemented in such a way as to form one or a plurality of other carrier reservoirs 154 in an upper portion of fin 104. According to a first example, a carrier reservoir 154 may be formed in an upper and central portion of fin 104, as shown in FIG. 14. According to a second example, a plurality of distinct carrier reservoirs 154 may be formed in an upper portion of fin 104, and aligned in a direction parallel to the length of fin 104 (parallel to the X axis). This or these other carrier reservoirs 154 may be obtained by implementing a masking step followed by a dopant implantation step, as for the previously-described forming of the carrier reservoirs 146. For simplification, this other carrier reservoir 154 is only shown in FIG. 14 and not in the following drawings.

An encapsulation layer 156 for example comprising an oxide such as SiO2 is then deposited in such a way as to encapsulate the unetched portions of the stack of layers 148, 150. The material of this encapsulation layer is in particular deposited around and between the unetched portions of the stack. A CMP may then be implemented to reach the thickness desired for encapsulation layer 156 (see FIG. 14).

In the described example, the remaining portions of hard mask layer 152 may be kept during the deposition of encapsulation layer 156, for example when the materials of hard mask layer 152 and of encapsulation layer 156 are identical. As a variant, and in particular when the materials of hard mask layer 152 and of encapsulation layer 156 are not identical, the remaining portions of hard mask layer 152 may be removed before the deposition of encapsulation layer 156.

To facilitate the removal of the layers of the second semiconductor 150, a mechanical holding structure may be formed on the stack of layers.

To form this structure, another layer of hard mask 158 is deposited on the structure obtained at this stage (see FIG. 15). A lithography is then implemented, and hard mask layer 158 is etched according to the pattern defined by this lithography (see FIG. 16).

Encapsulation layer 156 is then etched according to the pattern of hard mask layer 158 (see FIG. 17).

The layers of the second semiconductor 150 are then removed, for example by selective etching over the other materials present, in particular over the layers of the first semiconductor 148 (see FIG. 18). The presence of the remaining portions of encapsulation layer 156 enables to ensure the mechanical hold of the layers of first semiconductor 148.

Hard mask layer 158 is then removed (see FIG. 19).

Views b) of FIGS. 17 to 19 are such that the cutting axis AA does not run through the remaining portions of the layers of the first and second semiconductors 148, 150.

A conformal deposition of dielectric material over the entire structure is then implemented, forming in particular the first dielectric portions 112 and the second dielectric portions 120 between the layers of the first semiconductor 148 (see FIG. 20). The deposited dielectric material corresponds, for example, to SiO₂.

A partial etching of the deposited dielectric material is then implemented, in particular to remove the portions of this dielectric material covering the upper surfaces and the side flanks of the stacks comprising the portions of the layer of the first semiconductor 148 and the first and second dielectric portions 112, 120. The structure obtained at this stage is shown in FIG. 21.

A siliciding of the layers of the first semiconductor 148 can then be implemented (see FIG. 22).

An etching of the layers of the first semiconductor 148, of the first dielectric portions 112, and of the second dielectric portions 120 can then be implemented so that one of their ends is exposed and form electrical accesses to each of these elements. This etching completes the forming of the first and second 106, 114, as well as of the third and fourth gates 128, 130 (see FIG. 23).

Dielectric encapsulation material 132 may then be deposited in such a way as to cover the entire structure (see FIG. 24).

Device 100 can then be completed by forming the first and second electrical contacts 110, 118 as well as those electrically coupled to the third and fourth gates 128, 130, which contacts can be formed through dielectric encapsulation material 132, for example by etching the dielectric encapsulation material 132 and then filling the holes etched in dielectric encapsulation material 132 with one or a plurality of electrically-conductive materials. The device 100 obtained at the end of this process corresponds to that previously described in relation with FIG. 1.

In the above-described method, the different gates 106, 114, 128, 130 are formed by first forming a stack of alternating layers that can be selectively etched with respect to one another (for example, a Si/SiGe-type stack), and then selectively etching the layers of one of the two materials and filling the obtained spaces with a dielectric material to form the first and second dielectric portions 112, 120.

As a variant, it is possible to directly form a stack, alternately comprising layers of electrically-conductive material(s), for example in-situ doped polysilicon (amorphous or not) and/or one or a plurality of metallic materials, and layers of dielectric material, for example SiO₂. In this case, it is not necessary to form the mechanical holding structure nor to carry out the various previously-described steps enabling to replace the layers of the second semiconductor 150 with the first and second dielectric portions 112, 120. In this variant, it must however be ascertained that the successive implemented depositions leave no residual layers against the lateral surfaces 108, 116 of fin 104. If the implemented depositions leave such residual layers on the flanks of fin 104, steps of etching of these residual layers may be implemented between the deposition steps. In this case, it is possible to deposit, after each deposition of layers in the stack, an SOC-type planarizing layer, and then to etch the residual layer on the flanks of fin 104 and not covered by the planarizing layer. Alternatively to the use of a planarizing layer, it is possible to implement a CMP, and then to perform a partial removal of the deposited material to remove the residual layer.

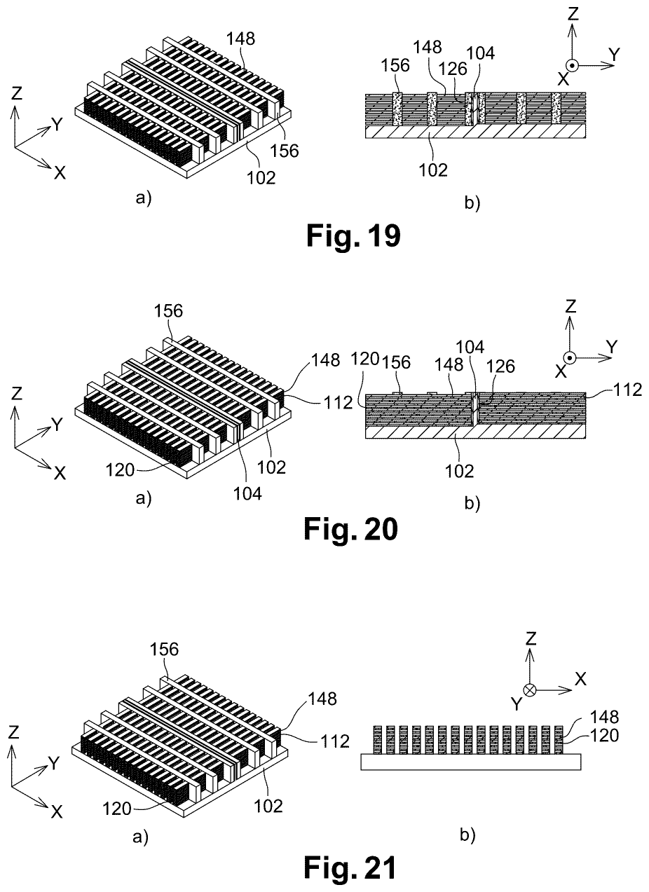

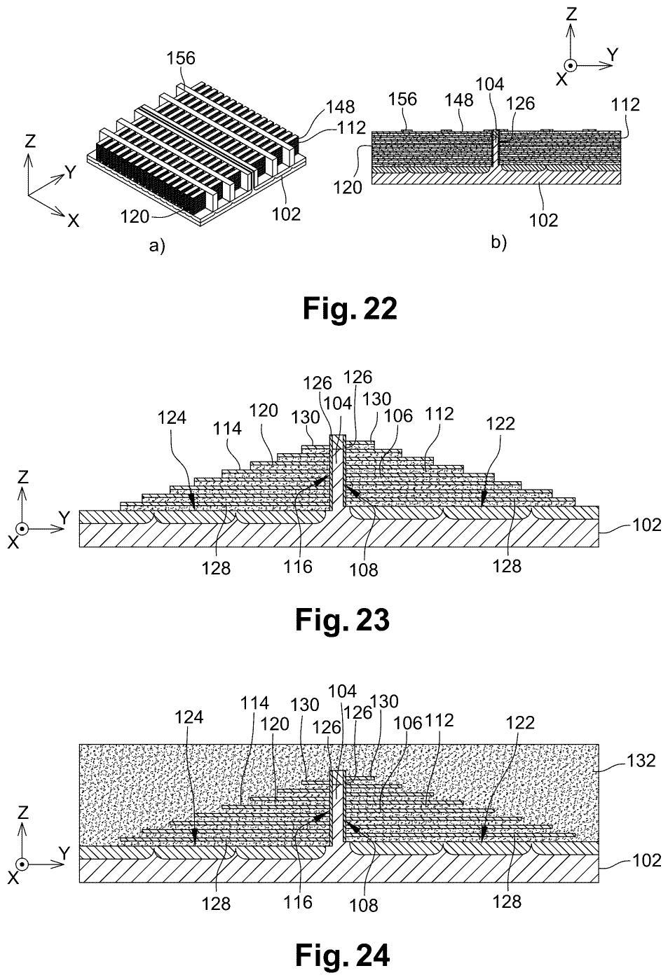

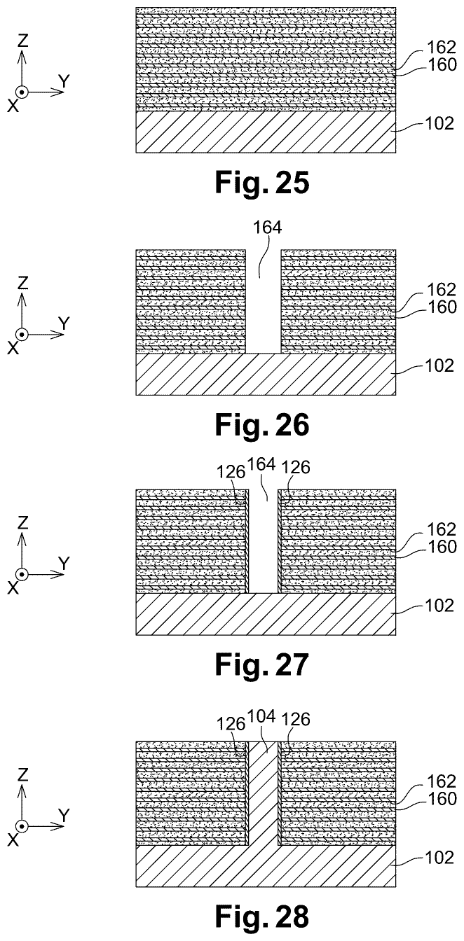

According to another alternative, to avoid problems linked to the possible presence of residual layers against the side walls of fin 104, it is possible to form the stack of layers of electrically-conductive material and of layers of dielectric material prior to the forming of fin 104. FIG. 25 shows such a stack in which reference 160 designates the layers of electrically-conductive material and reference 162 designates the layers of dielectric material.

An etching is then implemented through this stack of layers 160, 162, to form an opening 164 for fin 104 (FIG. 26). The etched opening corresponds, for example, to a trench.

Dielectric layer 126 can then be deposited against the flanks of opening 164 (see FIG. 27).

Fin 104 can then be formed in the remaining space of opening 164, for example by implementing an epitaxy from the bottom wall of opening 164 formed by support 102 (see FIG. 28).

As variant of the different previously-described embodiments, device 100 may comprise one or a plurality of fifth control gates arranged above the first gates 106, and one or a plurality of sixth control gates arranged above the second gates 114. In the presence of a plurality of fifth gates, these fifth gates are separate from one another and may be stacked one above the other. In the presence of a plurality of sixth gates, these sixth gates are separate from one another and may be stacked one above the other.

In this variant, the fifth gate or each of the fifth gates covers a portion of the first lateral surface 108. The sixth gate or each of the sixth gates covers a portion of the second lateral surface 116.

The fifth and sixth gates each for example have a length (dimension parallel to the length L of fin 104) and a height (dimension parallel to the height H of fin 104), for example, similar to those of the first gates 106 and/or of the second gates 114. The material(s) of these fifth and sixth gates are, for example, similar to those of the first gates 106 and/or of the second gates 114.

In this variant, the functions of the fifth and sixth gates are inverted with respect to those of the first and second gates 106, 114. Thus, the fifth gates are configured to control tunnel barriers, that is, to control the electrostatic potential of coupling regions intended to be formed between quantum dots, and the sixth gates are configured to control the electrostatic potential of quantum dots. Each of the fifth control gates is thus arranged in a gate level interposed between two other gate levels, each comprising one of the sixth control gates.

In the presence of such fifth and sixth gates, it is thus possible to have, on each side of semiconductor fin 104, that is, on the side of each of the first and second lateral surfaces 108, 116, gates controlling the potential of quantum dots and gates controlling the potential of the coupling regions.

In the different examples of embodiments and variants of the described device 100, the arrangement of the first and second gates 106, 114 in the form of a vertical stack with an offset between the first and second gates 106, 114 enables to significantly decrease the value of the pitch achievable between the gates for controlling the quantum dots, and thus to obtain, in the semiconductor fin, a very high density of quantum dots while allowing good compensation for the impact of electrically-charged defects present in the materials of device 100.

In the different previously-described examples of embodiment and variants of the device 100, a dimension of semiconductor fin 104 perpendicular to the first and second lateral surfaces 108, 116 (dimension parallel to the Y axis in the different drawings) is such that a single plane or two planes of quantum dots parallel to the first and second lateral surfaces 108, 116 (that is, parallel to the (X,Y) plane) are intended to be formed in semiconductor fin 104.

Various embodiments and variants have been described. The person skilled in the art will understand that certain features of these various embodiments and variants could be combined, and other variants will become apparent to the person skilled in the art.

Finally, the practical implementation of the described embodiments and variants is within the abilities of those skilled in the art, based on the indications given above. For example, the nature (wet, dry, etc.) of each of the implemented etchings may be selected according to the material(s) to be etched.

1. Electronic device comprising:
a support;
a semiconductor fin arranged on an upper surface of the support, in which quantum dots are intended to be formed, and comprising a first lateral surface and a second lateral surface opposite to the first lateral surface;
a plurality of first control gates, separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1,and Z corresponding to an integer greater than or equal to 2;
at least one second control gate arranged on the side of the second lateral surface, and configured to control the electrostatic potential of a coupling region intended to be formed between the quantum dots;
wherein the control gate(s) arranged on the side of the second lateral surface are offset, along the direction perpendicular to the upper surface of the support, with respect to the control gates arranged on the side of the first lateral surface and define one or more gate levels, each interposed between two other gate levels each comprising one of the control gates arranged on the side of the first lateral surface.

2. Electronic device according to claim 1, wherein a first portion of the upper surface of the support on which are arranged the first control gates is offset, along the direction perpendicular to the upper surface of the support, with respect to a second portion of the upper surface of the support on which is arranged the second control gate.

3. Electronic device according to claim 1, comprising a plurality of second control gates arranged on the side of the second lateral surface one above the other along the direction perpendicular to the upper surface of the support and defining different gate levels, configured to each control the electrostatic potential of a coupling region intended to be formed between two of the quantum dots,
wherein the second control gates are offset, along the direction perpendicular to the upper surface of the support, with respect to the first control gates, each of the second control gates being arranged in a gate level interposed between two other gate levels each comprising one of the first control gates.

4. Electronic device according to claim 3, further comprising a plurality of first dielectric portions arranged between the first control gates and a plurality of second dielectric portions arranged between the second control gates.

5. Electronic device according to claim 3, wherein, in a direction perpendicular to the lateral surfaces, each of the first control gates has a width different from those of the other first control gates and each of the second control gates has a width different from those of the other second control gates.

6. Electronic device according to claim 1, wherein a dimension of the semiconductor fin perpendicular to the first and second lateral surfaces is such that a single plane or two planes of quantum dots parallel to the first and second lateral surfaces are intended to be formed in the semiconductor fin.

7. Electronic device according to claim 1, wherein heights, along the direction perpendicular to the upper surface of the support, of the first and second control gates are equal to one another.

8. Electronic device according to claim 1, wherein, in a plane perpendicular to the upper surface of the support and perpendicular to the first and second lateral surfaces, the first and second control gates are aligned with respect to one another, or the first control gates are offset with respect to the second control gates.

9. Electronic device according to claim 1, comprising a plurality of distinct sets of first and second control gates arranged along a length of the semiconductor fin which corresponds to a dimension parallel to the first and second lateral surfaces and to the upper surface of the support.

10. Method of forming an electronic device, comprising:
forming a semiconductor fin on an upper surface of the support, in which quantum dots are intended to be formed, and comprising a first lateral surface and a second lateral surface opposite to the first lateral surface;
forming a plurality of first control gates separate from one another, arranged on the side of the first lateral surface, one above the other along a direction perpendicular to the upper surface of the support and defining different gate levels, configured to each control the electrostatic potential of one of the quantum dots, the first control gate closest to the support being arranged in a gate level N, and the first control gate most distant from the support being arranged in a gate level N+Z, with N corresponding to an integer greater than or equal to 1, and Z corresponding to an integer greater than or equal to 2;
forming at least one second control gate arranged on the side of the second lateral surface, and configured to control the electrostatic potential of a coupling region intended to be formed between the quantum dots;
wherein the control gate(s) arranged on the side of the second lateral surface are offset, along the direction perpendicular to the upper surface of the support, with respect to the control gates arranged on the side of the first lateral surface and define one or a plurality of gate levels each interposed between two other gate levels each comprising one of the control gates arranged on the side of the first lateral surface (108).

11. Method according to claim 10, wherein forming the semiconductor fin comprises at least one etching of the support, and wherein the first and second control gates are then formed on remaining portions of the support arranged on either side of the semiconductor fin.

12. Method according to claim 10, wherein forming the semiconductor fin comprises at least one epitaxial growth from a region of the support forming a bottom wall of an opening formed through a stack of layers arranged on the support and from which the first and second control gates are formed.

13. Method according to claim 10, wherein forming the first and second control gates comprises at least the implementation of the following steps:
forming a stack of layers of a first semiconductor and of layers of a second semiconductor arranged in alternating fashion one above the other, the first and second semiconductors being capable of being selectively etched with respect to one another;
etching of the stack in such a way that at least two remaining portions of the stack are each arranged against one of the first and second side walls;
selective removal of remaining portions of the layers of the second semiconductor present in the remaining portions of the stack;
deposition of at least one dielectric material in spaces formed by the selective removal of the remaining portions of the layers of the second semiconductor, forming first dielectric portions arranged between the first control gates and second dielectric portions arranged between a plurality of second control gates;
and wherein the semiconductor fin is formed before the stack.

14. Method according to claim 10, wherein forming the first and second control gates comprises at least the implementation of the following steps:
forming a stack of layers of an electrically-conductive material and of layers of a dielectric material arranged in alternating fashion one above the other;
etching of the stack in such a way that at least two remaining portions of the stack are each arranged against one of the first and second side walls;
wherein the stack of layers is formed after the semiconductor fin and by implementing successive steps of deposition of the layers of electrically-conductive material and of the layers of dielectric material and, between the deposition steps, steps of removal of portions of the layers of electrically-conductive material and of the layers of dielectric material deposited against the first and second lateral surfaces.

15. Method according to claim 10, wherein forming the first and second control gates comprises at least the implementation of the following steps:
forming a stack of layers of an electrically-conductive material and of layers of a dielectric material arranged in alternating fashion one above the other;
etching of the stack in such a way that at least two remaining portions of the stack of layers are each arranged against one of the first and second side walls;
and wherein the semiconductor fin is formed after the stack.
